(19) United States
(12) Patent Application Publication
(10) Pub. No.: US 2010/0032017 A1
(43) Pub. Date: Feb. 11, 2010

(54) SOLAR CELL AND METHOD OF MANUFACTURING THE SAME

(76) Inventor: Joo-Han Bae, Suwon-si (KR)

Correspondence Address: F. CHAU & ASSOCIATES, LLC, 130 WOODBURY ROAD, WOODBURY, NY, 11797, US

(21) Appl. No.: 12/463,724

(22) Filed: May 11, 2009

(30) Foreign Application Priority Data
Aug. 5, 2008 (KR) 10-2008-0076669

(51) Int. Cl. H01L 31/00; H01L 31/0224

(52) U.S. Cl. 136/261; 438/98; 257/E31.124

(57) ABSTRACT

In a solar cell and a method of manufacturing the solar cell, when a semiconductor pattern, bottom electrodes and top electrodes are patterned, a first mask pattern having different thicknesses according to location, a second mask pattern formed by etching back the first mask pattern, and a third mask pattern by etching back the second mask pattern are used etch masks. The first mask pattern may be easily manufactured using an imprint method utilizing a mold.

### CROSS-REFERENCE TO RELATED APPLICATION

This application claims priority to Korean Patent Application No. 2008-76669 filed on Aug. 5, 2008, the contents of which are herein incorporated by reference in their entirety.

### BACKGROUND

1. Technical Field

The present invention relates to a solar cell and a method of manufacturing the same, and more particularly, to a solar cell having improved photoelectric efficiency and a method easily manufacturing same.

2. Discussion of the Related Art

A solar cell converts optical energy into electrical energy, and includes first and second electrodes, and a semiconductor layer interposed between the first and second electrodes. The semiconductor layer has a junction structure of a P type semiconductor and an N type semiconductor, or a junction structure of a P type semiconductor, an N type semiconductor and an intrinsic semiconductor interposed between the P type and N type semiconductors. The semiconductor layer causes a photoelectric effect by absorbing optical energy to generate free electrons, thereby generating electric current.

In order to form a plurality of solar cells electrically interconnected in series on a substrate, source layers are formed on the substrate, and then are patterned to form the semiconductor layer, and the first and second electrodes. As a result of patterning the source layers using a laser, two adjacent cells may be electrically shorted with each other or the semiconductor layer may be damaged. Thus, photoelectric efficiency of the solar cell is degraded.

### SUMMARY

Exemplary embodiments of the present invention provide a solar cell having improved reliability, and a method of easily manufacturing the solar cell.

In an exemplary embodiment of the present invention, a solar cell includes a substrate, a plurality of bottom electrodes, a semiconductor pattern and a plurality of top electrodes. The substrate has a plurality of cell areas and a cell isolation area between two adjacent cell areas. A bottom electrode is provided on the substrate in each cell area. The semiconductor pattern is provided on the bottom electrodes. A space between bottom electrodes of two adjacent cell areas is defined in the cell isolation area. The top electrodes are provided on the semiconductor pattern.

In an exemplary embodiment of the present invention, a method of manufacturing a solar cell is provided as follows. A substrate having a plurality of cell areas and a cell isolation area between two adjacent cell areas is provided. A first conductive layer is formed on the substrate. A semiconductor layer is formed on the first conductive layer. A first mask pattern, which has at least one first opening corresponding to the cell isolation area, is formed over the semiconductor layer.

After the first mask pattern is formed, a preliminary semiconductor pattern is formed by patterning the semiconductor layer using the first mask pattern. Bottom electrodes are formed in the respective cell areas by removing the first conductive layer from the cell isolation area by using the first mask pattern. A second mask pattern having second openings is formed by etching the first mask pattern.

After the second mask pattern is formed, a semiconductor pattern is formed by patterning the preliminary semiconductor pattern using the second mask pattern. The bottom electrodes are exposed at locations corresponding to the second openings. Upper electrodes are formed on the semiconductor pattern to be electrically connected with the exposed bottom electrodes.

A solar cell, according to an embodiment of the present invention, comprises a substrate having a plurality of cell areas and a cell isolation area between two adjacent cell areas, a bottom electrode provided on the substrate in each cell area, an undercut section formed in the cell isolation area, wherein the undercut section defines a space between the bottom electrodes in the two adjacent cell areas, a semiconductor pattern provided on the bottom electrodes, and a plurality of top electrodes provided on the semiconductor layer.

A top electrode of the plurality of top electrodes may overlap the two adjacent cell areas. The solar cell may further comprise a contact hole formed in the semiconductor pattern, wherein the top electrode is electrically connected to a bottom electrode corresponding to one of the two adjacent cell areas through the contact hole.

According to the embodiments of the present invention, the semiconductor pattern, the bottom electrodes and the top electrodes can be easily patterned through an etching process by using etch masks in the sequence of the first mask pattern, which has different thicknesses according to location, the second mask pattern, which is formed by etching back the first mask pattern, and the third mask pattern, which is formed by etching back the second mask pattern.

### BRIEF DESCRIPTION OF THE DRAWINGS

Embodiments of the present invention will become readily apparent by reference to the following detailed description when considered in conjunction with the accompanying drawings wherein:

FIG. 1 is a plan view illustrating a photoelectric device according to an exemplary embodiment of the present invention;

FIG. 2A is a sectional view taken along line I-I′ in FIG. 1;

FIG. 2B is a sectional view taken along line II-II′ in FIG. 1;

FIG. 3 is a sectional view illustrating a photoelectric device according to an exemplary embodiment of the present invention;

FIGS. 4A, 5A, 6A, 7A and 8A are plan views illustrating a manufacturing process of the photoelectric device shown in FIG. 1;

FIGS. 4B, 5B, 6B, 7B and 8B are sectional views taken along lines I-I′ in FIGS. 4A, 5A, 6A, 7A and 8A, respectively;

FIGS. 4C, 5C, 6C, 7C and 8C are sectional views taken along lines II-II′ in FIGS. 4A, 5A, 6A, 7A and 8A, respectively;

FIG. 9 is a sectional view illustrating a manufacturing process after the manufacturing process of the photoelectric device shown in FIG. 8B; and

FIGS. 10 and 11 are sectional views illustrating a method of manufacturing the first photoresist pattern shown in FIG. 4B.

### DESCRIPTION OF THE EMBODIMENTS

Hereinafter, embodiments of the present invention will be explained in detail with reference to the accompanying drawings. However, the scope of the present invention is not limited to such embodiments and the present invention may be realized in various forms. The size of layers and regions shown in the drawings can be simplified or magnified for the purpose of clear explanation. Also, the same reference numerals may be used to designate the same elements throughout the drawings.

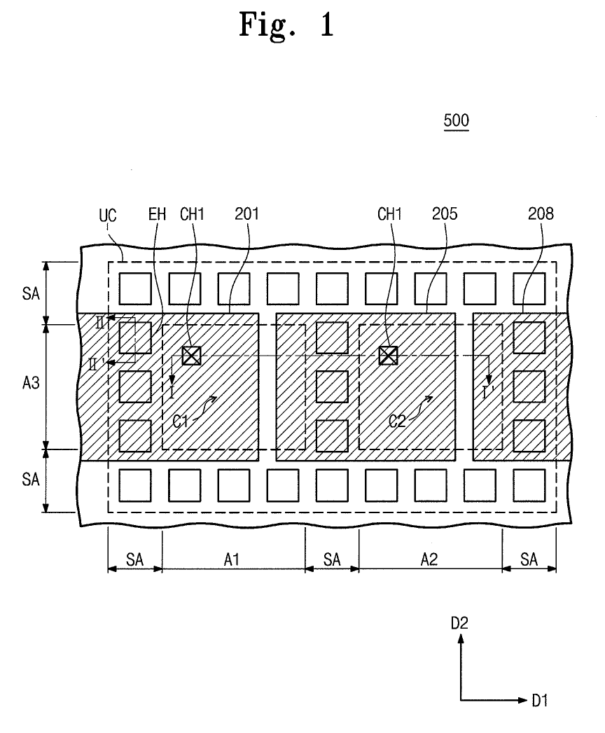

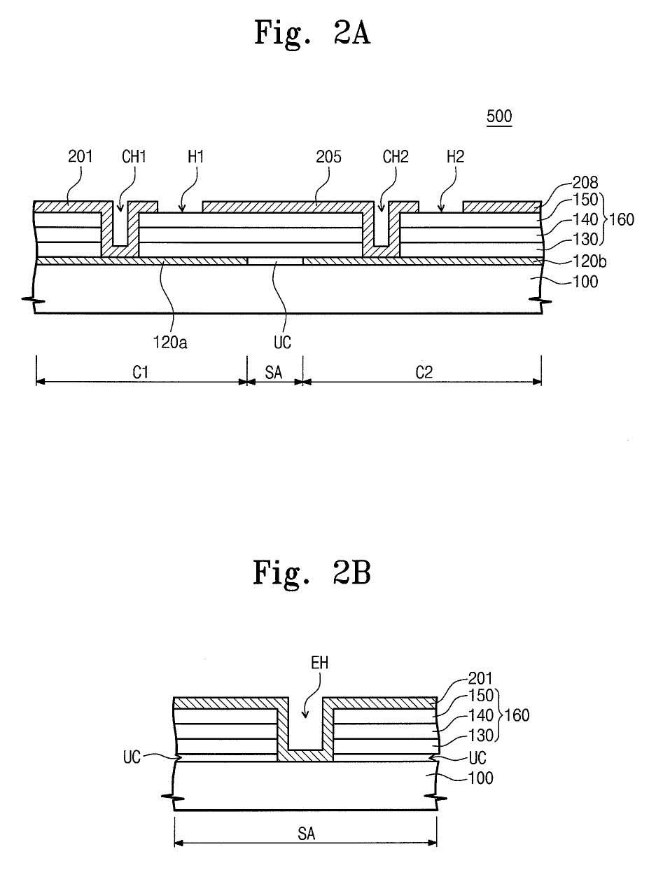

FIG. 1 is a plan view illustrating a photoelectric device according to an exemplary embodiment of the present invention and FIG. 2a is a sectional view taken along line I-I′ in FIG. 1.

The photoelectric device 500 includes a substrate 100 having a plurality of cell areas and a plurality of cells respectively corresponding to the cell areas. The cells have the same structure as each other. FIG. 1 shows only cells electrically connected in series with each of first and second cell areas C1 and C2.

Referring to FIGS. 1 and 2A, the photoelectric device 500 includes the first and second cell areas C1 and C2, and a cell isolation area SA between two adjacent cell areas. The first cell area C1 partially overlaps a first area A1 and a third area A3, and the second cell area C2 partially overlaps a second area A2 and the third area A3 when viewed in a plan view.

In the first and second cell areas C1 and C2, first and second bottom electrodes 120a and 120b are provided on the substrate 100, respectively. A semiconductor pattern 160 is provided on the first and second bottom electrodes 120a and 120b, and first to third top electrodes 201, 205 and 208 are provided on the semiconductor pattern 160.

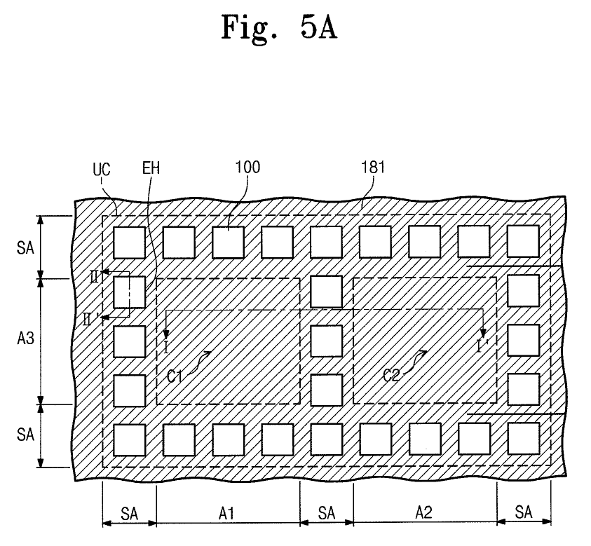

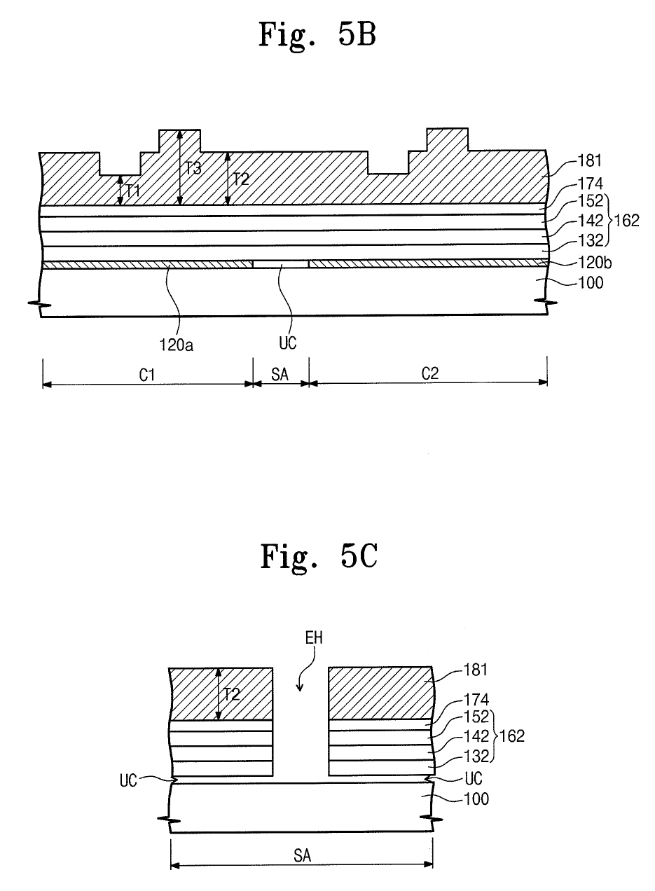

The first and second bottom electrodes 120a and 120b include a transparent conductive layer such as, for example, indium tin oxide (ITO) and indium zinc oxide (IZO). The first and second bottom electrodes 120a and 120b are spaced apart from each other while interposing the cell isolation area SA therebetween. This is the result of an undercut section UC that is formed below the semiconductor pattern 160 in the cell isolation area SA due to undercut effect. The undercut section UC will be described in further detail with reference to FIGS. 5A to 5C.

The semiconductor pattern 160 causes photoelectric effect using energy of external light. The semiconductor pattern 160 includes an N type semiconductor pattern 130 making contact with the first and second bottom electrodes 120a and 120b, a P type semiconductor pattern 150 making contact with the first to third top electrodes 201, 205 and 208, and an intrinsic semiconductor pattern 140 interposed between the N type semiconductor pattern 130 and the P type semiconductor pattern 150.

The N type semiconductor pattern 130 includes semiconductor material, such as silicon doped with phosphorous (P), which has a larger electron density than hole density. The P type semiconductor pattern 150 includes semiconductor material, such as silicon doped with boron (B), which has a larger hole density than electron density. Further, the intrinsic semiconductor pattern 140 includes semiconductor material such as crystalline silicon or amorphous silicon in which the number of electrons is similar to the number of holes.

The semiconductor pattern 160 is removed from first and second contact holes CH1 and CH2, so that the first top electrode 201 is electrically connected with the first bottom electrode 120a through the first contact hole CH1, and the second top electrode 205 is electrically connected with the second bottom electrode 120b through the second contact hole CH2. Although not shown in FIGS. 1 and 2A, the third top electrode 208 is electrically connected with another bottom electrode adjacent to the second bottom electrode 120b.

The first to third top electrodes 201, 205 and 208 are spaced apart from each other. In more detail, the first and second top electrodes 201 and 205 are spaced apart from each other while interposing a first opening H1 therebetween and the second and third top electrodes 205 and 208 are spaced apart from each other while interposing a second opening H2 therebetween.

A plurality of etching holes EH are formed in the cell isolation area SA. Referring to FIG. 1, two adjacent etching holes are arranged in a first direction D1 or a second direction D2 perpendicular to the first direction D1. As shown in FIG. 2B, the semiconductor pattern 160 is removed from each etching hole EH and the undercut sections UC are formed below the semiconductor pattern 160 around the etching holes EH. The number of the etching holes EH may vary depending on conditions of an etching process of forming the undercut section UC and the sizes of the first and second cell areas C1 and C2.

FIG. 2B is a sectional view taken along line II-II′ in FIG. 1.

Referring to FIG. 2B, the semiconductor pattern 160 is removed from the etching hole EH, so that the first top electrode 201 is deposited in the etching hole EH. As described above, since the undercut section UC is formed below the semiconductor pattern 160 in the cell isolation area SA, the first top electrode 201 is not electrically shorted with the first bottom electrode 120a in the cell isolation area SA.

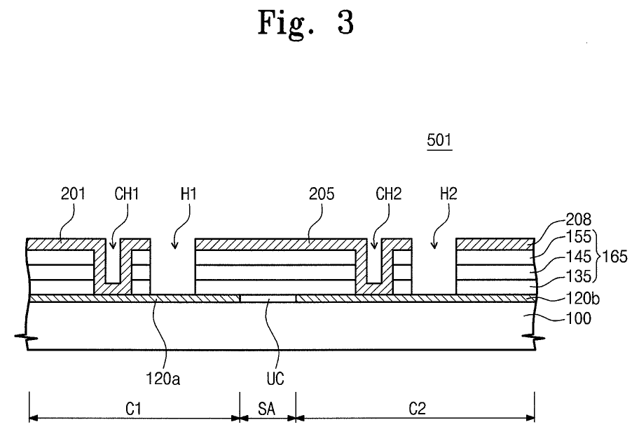

FIG. 3 is a sectional view illustrating a photoelectric device according to an exemplary embodiment of the present invention. The photoelectric device 500 shown in FIG. 2A is substantially identical to the photoelectric device 501 shown in FIG. 3, except for the structure of the semiconductor patterns 160 and 165 shown in FIGS. 2A and 3.

Referring to FIG. 3, the semiconductor pattern 165 includes a P type semiconductor pattern 155, an intrinsic semiconductor pattern 145 and an N type semiconductor pattern 135. The semiconductor pattern 165 may be removed from the first and second contact holes CH1 and CH2 as well as the first and second openings H1 and H2. When the semiconductor pattern 165 is removed from the first and second openings H1 and H2, a semiconductor layer (not shown) serving as a source of the semiconductor pattern 165 is formed on the substrate 100, a conductive layer serving as a source layer of the first to third top electrodes 201, 205 and 208 is formed on the semiconductor layer, and then the semiconductor layer and the source layer are substantially simultaneously patterned through a single etching process.

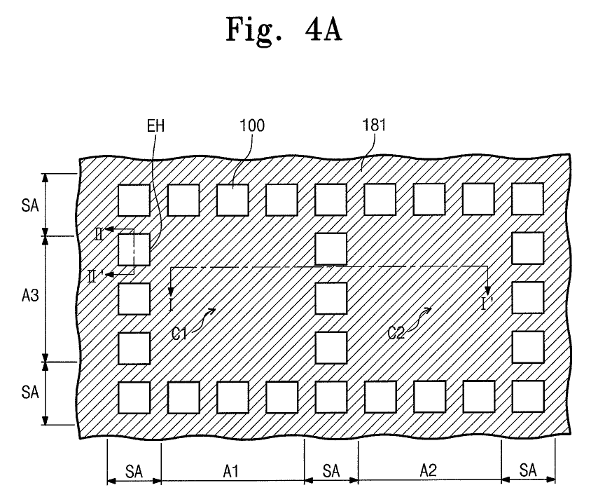

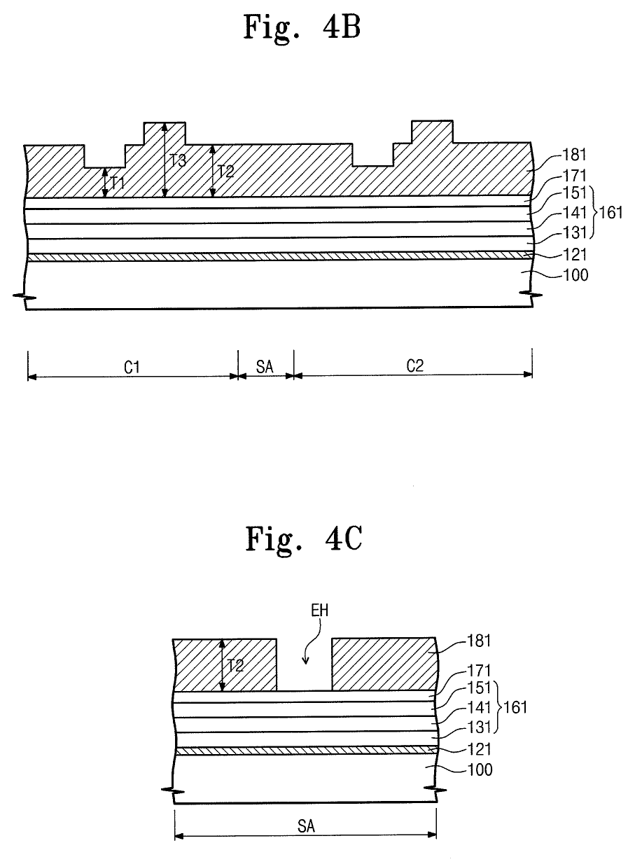

FIGS. 4A, SA, 6A, 7A and 8A are plan views illustrating a manufacturing procedure of the photoelectric device shown in FIG. 1. FIGS. 4B, 5B, 6B, 7B and 8B are sectional views taken along lines I-I′ in FIGS. 4A, SA, 6A, 7A and 8A, respectively, and FIGS. 4C, 5C, 6C, 7C and 8C are sectional views taken along lines II-II′ in FIGS. 4A, 5A, 6A, 7A and 8A, respectively.

Referring to FIGS. 4A, 4B and 4C, a first conductive layer 121 is formed on the substrate 100 including the first and second cell areas C1 and C2, and a preliminary semiconductor layer 161 including an N type preliminary semiconductor layer 131, a preliminary intrinsic semiconductor layer 141, and a P type preliminary semiconductor layer 151 is formed on the first conductive layer 121.

An etching assistant layer 171 is formed on the preliminary semiconductor layer 161. Then, a first mask pattern 181 is formed on the etching assistant layer 171. A plurality of etching holes EH are formed in the first mask pattern 181 in the cell isolation area SA while being spaced apart from each other, so that the substrate 100 is exposed through the etching holes EH.

The first mask pattern 181 has different thicknesses according to location. In more detail, the first mask pattern 181 has a first thickness T1 corresponding to the first and second contact holes CH1 and CH2 in FIG. 2A, and has a third thickness T3, which is larger than the first thickness T1, corresponding to the first and second openings H1 and H2 in FIG. 2A. Further, the first mask pattern 181 has a second thickness T2, which is larger than the first thickness T1 and smaller than the third thickness T3, corresponding to the first to third top electrodes 201, 205 and 208 except for areas having the first and second contact holes. According to an exemplary embodiment, for the purpose of convenience, the second thickness T2 is about twice as thick as the first thickness T1 and the third thickness T3 is about three times as thick as the first thickness T1.

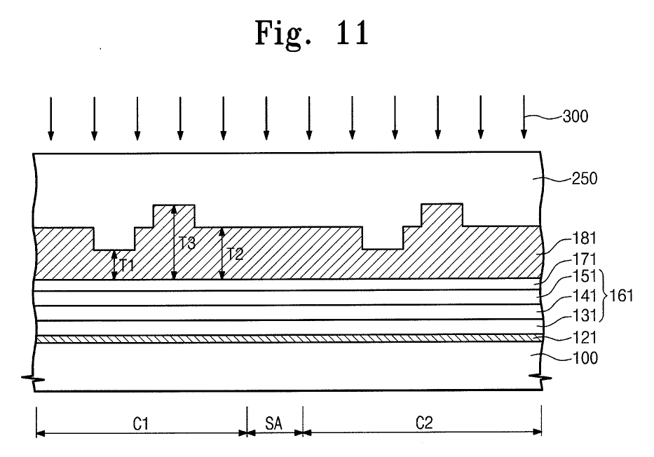

The first mask pattern 181 can be formed using an imprint method utilizing a mold. Hereinafter, a method of manufacturing the first mask pattern 181 will be described in more detail with reference to FIGS. 10 and 11.

FIGS. 10 and 11 are sectional views illustrating a method of manufacturing the first photoresist pattern shown in FIG. 4B.

Referring to FIGS. 10 and 11, the first conductive layer 121, the preliminary semiconductor layer 161 and the etching assistant layer 171 are sequentially formed on the substrate 100, and a photoresist layer 184 is formed on the etching assistant layer 171. Next, the photoresist layer 184 is compressed by a mold 250, so that the photoresist layer 184 has a concave-convex shape corresponding to the surface shape of the first mask pattern 181.

Then, a light 300 is irradiated onto the photoresist layer 184 to cure the photoresist layer 182. As a result, the first mask pattern 181 corresponding to the surface shape of the mold 250 is completed.

Referring to FIGS. 5A to 5C, the etching assistant layer 171, the preliminary semiconductor layer 161 and the first conductive layer 121 are sequentially etched using the first mask pattern 181 having the etching holes EH to form a first etching assistant pattern 174, a first preliminary semiconductor pattern 162, and the first and second bottom electrodes 120a and 120b. As a result, openings corresponding to the positions and shapes of the etching holes EH are formed in the first etching assistant pattern 174 and the first preliminary semiconductor pattern 162 through the etching process.

When the etching process is performed, openings corresponding to the positions and shapes of the etching holes EH are formed in the first conductive layer 121, and the first conductive layer 121 adjacent to the etching holes EH is also etched, so that the undercut section UC is formed below the first preliminary semiconductor pattern 162. As etching time of the etching process increases, the undercut section UC is gradually formed in a direction away from each etching hole EH, as shown in a plan view. If the etching time of the etching process exceeds a predetermined time, undercut sections formed in two adjacent etching holes are combined into one. As a result, as illustrated in FIG. 5A, the undercut sections UC are combined with each other in the cell isolation area SA, so that the first and second bottom electrodes 120a and 120b are spaced apart from each other by the undercut sections UC.

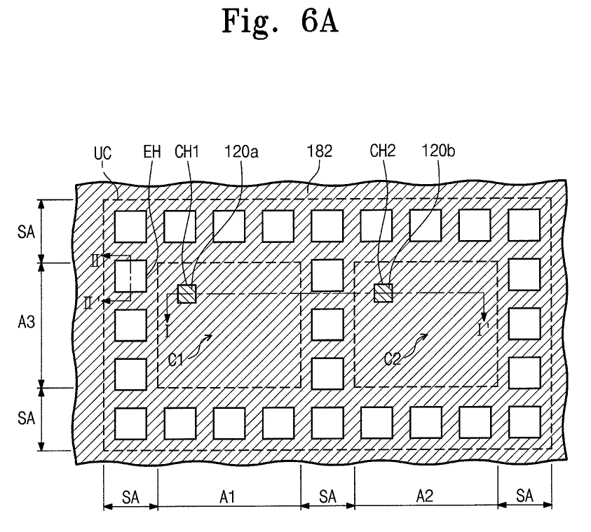

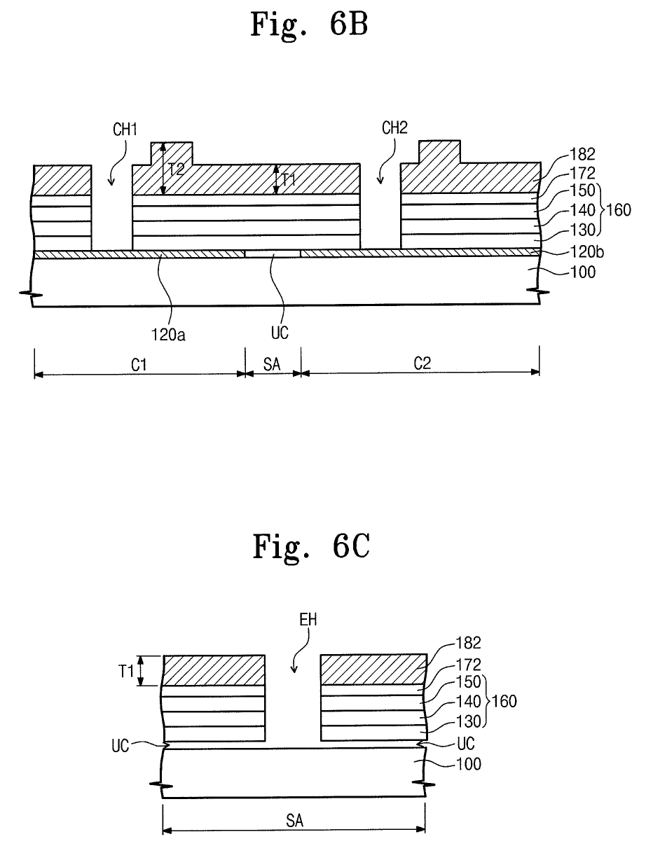

Referring to FIGS. 6A to 6C, the first mask pattern 181 is removed by the first thickness T1 to form a second mask pattern 182. Referring again to FIG. 5B, as the second mask pattern 182 is formed, the second mask pattern 182 is opened through the first and second contact holes CH1 and CH2 and has the second thickness T2 corresponding to the first and second openings H1 and H2.

After the second mask pattern 182 is formed, the first etching assistant pattern 174 and the first preliminary semiconductor pattern 162 are sequentially etched using the second mask pattern 182 to form a second etching assistant pattern 172 and the semiconductor pattern 160. As a result, the first bottom electrode 120a is exposed through the first contact hole CH1 and the second bottom electrode 120b is exposed through the second contact hole CH2.

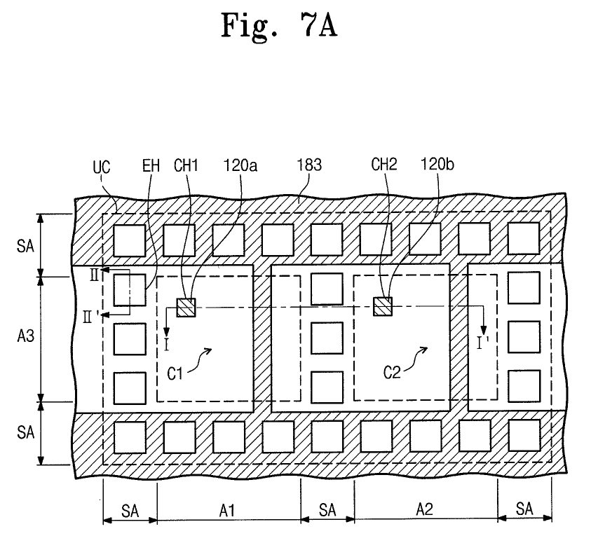

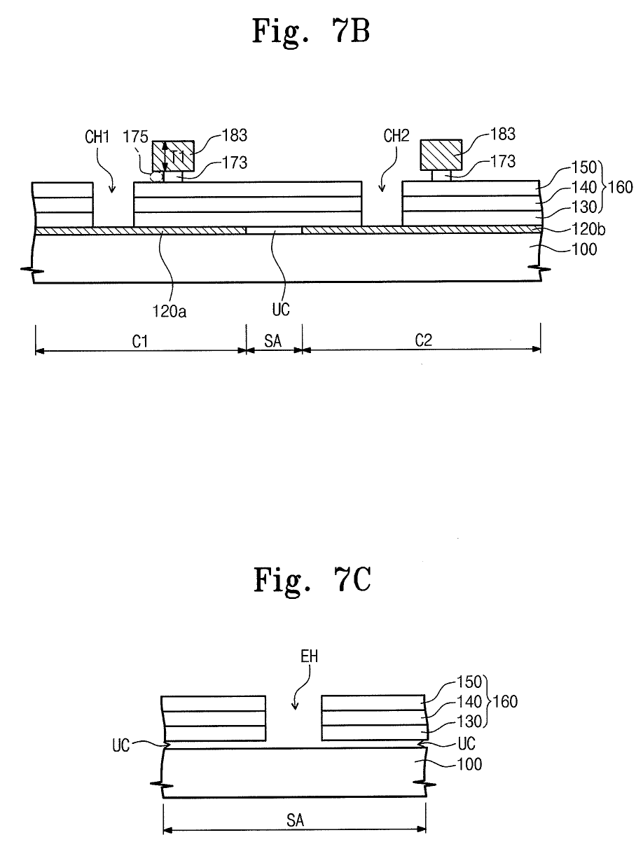

Referring to FIGS. 7A to 7C, the second mask pattern 182 is removed by the first thickness T1 to form a third mask pattern 183. Referring again to FIG. 6B, as the third mask pattern 183 is formed, the third mask pattern 183 has the first thickness T1 corresponding to an area where the top electrodes 201, 205 and 208 are not formed.

After the third mask pattern 183 is formed, the second etching assistant pattern 172 is etched using the third mask pattern 183 to form a third etching assistant pattern 173. When the second etching assistant pattern 172 is etched using the third mask pattern 183, the third etching assistant pattern 173 is etched such that an undercut 175 is formed below the third mask pattern 183.

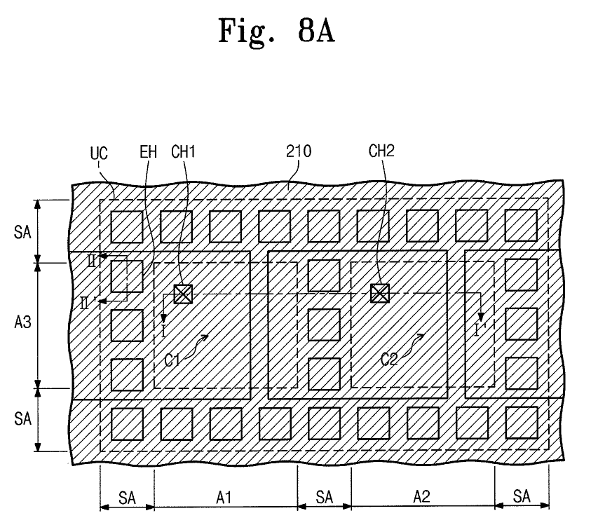

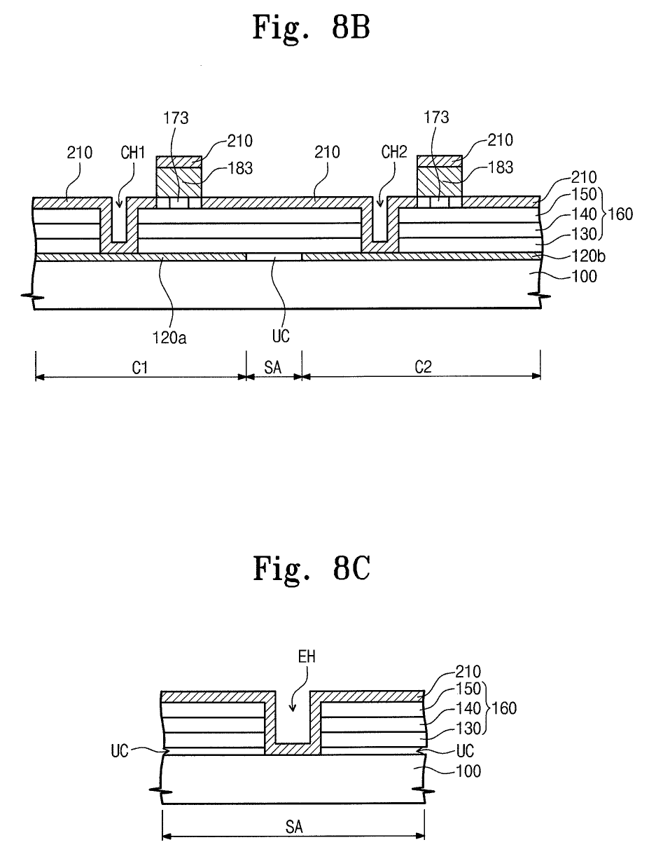

Referring to FIGS. 8A to 8C, a second conductive layer 210 is formed on the substrate 100. As a result, the second conductive layer 210 is partially formed on the third mask pattern 183 and is formed on the first and second bottom electrodes 120a and 120b in the first and second contact holes CH1 and CH2, so that the second conductive layer 210 is electrically connected with the first and second bottom electrodes 120a and 120b.

Further, the second conductive layer 210 is deposited in the etching holes EH. Since the undercut section UC is formed around the etching holes EH, the second conductive layer 210 deposited in the etching holes EH is not electrically shorted with the first or second bottom electrode 120a or 120b.

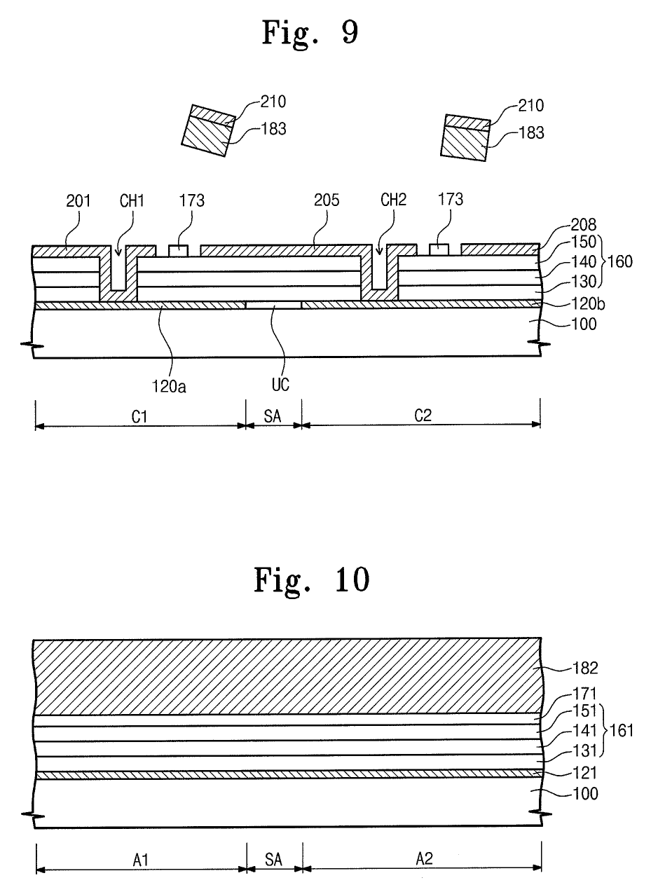

FIG. 9 is a sectional view illustrating a manufacturing process after the photoelectric device shown in FIG. 8B has been manufactured.

Referring to FIG. 9, the third mask pattern 183 having the second conductive layer 210 thereon is removed to form the first to third top electrodes 201, 205 and 208 spaced apart from each other. As illustrated in FIGS. 7B and 8B, since the undercut 175 is formed below the third mask pattern 183, the third mask pattern 183 can be easily removed using a lift-off method.

After the first to third top electrodes 201, 205 and 208 are formed, the third etching assistant pattern 173 is removed, thereby completing fabrication of the solar cell 500 of FIG. 1. The third etching assistant pattern 173 can be removed using a conventional photolithography method or using etching material that selectively etches only the third etching assistant pattern 173.

According to the solar cell and the manufacturing method of solar cell according to embodiments of the present invention, the semiconductor pattern, the bottom electrode and the top electrode can be easily patterned through an etching process by using etch masks in the sequence of the first mask pattern, which has different thicknesses according to location, the second mask pattern, which is formed by etching back the first mask pattern, and the third mask pattern, which is formed by etching back the second mask pattern.

Although exemplary embodiments of the present invention have been described, it is understood that the present invention should not be limited to these exemplary embodiments but various changes and modifications can be made by one ordinary skilled in the art within the spirit and scope of the present invention as hereinafter claimed.

What is claimed is:

1. A method of manufacturing a solar cell, the method comprising:
preparing a substrate having a plurality of cell areas and a cell isolation area between two adjacent cell areas;
forming a first conductive layer on the substrate;
forming a semiconductor layer on the first conductive layer;
forming a first mask pattern over the semiconductor layer, wherein the first mask pattern includes at least one first opening corresponding to the cell isolation area;
patterning the semiconductor layer using the first mask pattern to form a preliminary semiconductor pattern, and removing the first conductive layer from the cell isolation area by using the first mask pattern to form bottom electrodes in the cell areas;
etching the first mask pattern to form a second mask pattern having second openings;
patterning the preliminary semiconductor pattern using the second mask pattern to form a semiconductor pattern and to expose the bottom electrodes at locations corresponding to the second openings; and
forming upper electrodes electrically connected with the exposed bottom electrodes on the semiconductor pattern.

2. The method of claim 1, wherein the forming the semiconductor layer comprises:
forming an N type semiconductor layer on the first conductive layer;
forming an intrinsic semiconductor layer on the N type semiconductor layer; and
forming a P type semiconductor layer on the intrinsic semiconductor layer.

3. The method of claim 1, wherein:
the first mask pattern has first to third thicknesses corresponding to first to third areas, respectively,
the second thickness is larger than the first thickness and the third thickness is larger than the second thickness,
the first area corresponds to an area where the top electrodes are formed above the bottom electrodes so that the top electrodes are electrically connected the bottom electrodes,
the second area corresponds to an area where the top electrodes are formed on the semiconductor pattern, and
the third area corresponds to an area where the top electrodes are removed.

4. The method of claim 3, further comprising:
forming an etching assistant layer between the semiconductor layer and the first mask pattern;
etching the etching assistant layer using the first mask pattern to form a first preliminary etching assistant pattern;
etching the first preliminary etching assistant pattern using the second mask pattern to form a second preliminary etching assistant pattern; and
etching the second mask pattern to form a third mask pattern covering the third area.

5. The method of claim 4, wherein the forming the top electrodes comprises:
forming a second conductive layer on an entire surface of the substrate after forming the third mask pattern; and
removing the third mask pattern,
wherein the second conductive layer is formed on the bottom electrodes in the first area so that the second conductive layer is electrically connected with the bottom electrodes, is formed on the semiconductor pattern in the second area, and is formed on the third mask pattern in the third area.

6. The method of claim 3, wherein the forming the first mask pattern comprises:
forming an insulating layer on the first conductive layer;
compressing the insulating layer by using a mold; and
curing the compressed insulating layer by using heat or light.

7. The method of claim 1, wherein the bottom electrodes are formed by an undercut generated in the first conductive layer below the preliminary semiconductor pattern around the first opening.

8. The method of claim 3, wherein the semiconductor pattern is removed from the third area.

9. The method of claim 1, wherein the semiconductor pattern causes a photoelectric effect using energy of light incident through the bottom electrodes.

10. A solar cell comprising:
a substrate having a plurality of cell areas and a cell isolation area between two adjacent cell areas;
a bottom electrode provided on the substrate in each cell area;
a semiconductor pattern provided on the bottom electrodes, wherein a space is defined between the bottom electrodes in the cell isolation area between the two adjacent cell areas; and
a plurality of top electrodes provided on the semiconductor pattern.

11. The solar cell of claim 10, wherein the semiconductor pattern comprises:
an N type semiconductor pattern provided on the bottom electrodes;
an intrinsic semiconductor pattern provided on the N type semiconductor pattern; and
a P type semiconductor pattern provided on the intrinsic semiconductor pattern.

12. The solar cell of claim 10, wherein the top electrodes overlap the two adjacent cell areas.

13. The solar cell of claim 12, wherein a cell area includes a contact hole from which the semiconductor pattern is removed, and a top electrode electrically connected with a bottom electrode through the contact hole.

14. The solar cell of claim 10, wherein the semiconductor pattern has an opening formed in an area where the top electrode is removed.

15. The solar cell of claim 10, wherein the semiconductor pattern causes a photoelectric effect using energy of light incident through the bottom electrodes.

16. A solar cell comprising:
a substrate having a plurality of cell areas and a cell isolation area between two adjacent cell areas;
a bottom electrode provided on the substrate in each cell area;
an undercut section formed in the cell isolation area, wherein the undercut section defines a space between the bottom electrodes in the two adjacent cell areas;
a semiconductor pattern provided on the bottom electrodes; and
a plurality of top electrodes provided on the semiconductor layer.

17. The solar cell of claim 16, wherein a top electrode of the plurality of top electrodes overlaps the two adjacent cell areas.

18. The solar cell of claim 17, further comprising a contact hole formed in the semiconductor pattern, wherein the top electrode is electrically connected to a bottom electrode corresponding to one of the two adjacent cell areas through the contact hole.
